(19) United States
(12) Patent Application Publication
(10) Pub. No.: US 2024/0030228 A1
(43) Pub. Date: Jan. 25, 2024

(54) ARRAY SUBSTRATE AND DISPLAY PANEL

(71) Applicant: WUHAN CHINA STAR OPTOELECTRONICS TECHNOLOGY CO., LTD., Wuhan (CN)

(72) Inventors: Tao MA, Wuhan (CN); Zhilin WU, Wuhan (CN); Fei AI, Wuhan (CN)

(73) Assignee: WUHAN CHINA STAR OPTOELECTRONICS TECHNOLOGY CO., LTD., Wuhan (CN)

(21) Appl. No.: 17/600,143

(22) PCT Filed: Sep. 13, 2021
(86) PCT No.: PCT/CN2021/118026

§ 371 Date: Sep. 30, 2021

(30) Foreign Application Priority Data
Aug. 4, 2021 (CN) 202110891996.X

(51) Int. Cl. H01L 27/12

(52) U.S. Cl. CPC H01L 27/124

(57) ABSTRACT

An array substrate and a display panel are disclosed. The array substrate includes an underlay, a seed layer disposed on one side of the underlay, and a first metal layer disposed on one side of the seed layer and away from the underlay, wherein the first metal layer directly contacts the seed layer. The present application utilizes the seed layer directly contacting the first metal layer to induce crystallization of the first metal layer, so that the first metal layer is formed with larger grains, fewer grain boundaries and less charge carrier scattering, and a resistivity of the first metal layer is decreased.

### FIELD OF INVENTION

The present application relates to a field of a display, and more particularly to an array substrate and a display panel.

### BACKGROUND OF INVENTION

Flat panel displays, such as a liquid crystal display (LCD) and the like, have advantages including the high picture quality, the power-saving property, the thin body, the wide application range and the like, are thus widely applied to various consumer electronic products including mobile phones, televisions, personal digital assistants, digital cameras, notebook computers, desktop computers and the like, and thus become the mainstream of display devices. The LCDs have two types of display technologies corresponding to amorphous silicon (A-Si) thin film transistors (TFTs) and low-temperature poly-silicon (LTPS) TFTs. Because the LTPS TFTs have the advantage of high mobility, they are widely used in the high-specification panel technology.

At present, the molybdenum (Mo) metal is mostly used in the industry to form a first metal layer wire in the LTPS TFT display product because the first metal layer wire is restricted by the high-temperature process at the temperature of about 600° C., for example. However, the Mo metal has the higher impedance, which is disadvantageous to the product requirement of the high charging rate of the high resolution, high frequency and middle-size product.

### SUMMARY OF INVENTION

### Technical Problem

The present application provides an array substrate and a display panel capable of reducing a resistivity of a first metal layer.

### Technical Solutions

The present application provides an array substrate including: an underlay, a seed layer disposed on one side of the underlay, and a first metal layer disposed on one side of the seed layer and away from the underlay, wherein the first metal layer directly contacts the seed layer.

In the array substrate of the present application, a lattice structure of the first metal layer is the same as a lattice structure of the seed layer.

In the array substrate of the present application, a ratio of a difference between a lattice constant of the first metal layer and a lattice constant of the seed layer to the lattice constant of the first metal layer is smaller than or equal to 20%.

In the array substrate of the present application, a lattice constant of the first metal layer is the same as a lattice constant of the seed layer.

In the array substrate of the present application, the lattice structures of the first metal layer and the seed layer are body-centered cubic lattices, and the lattice constant is 3.14 pm.

In the array substrate of the present application, the seed layer has a thickness ranging from 50 to 1000 angstroms, a material of the seed layer may be at least one of tungsten, niobium, tantalum, a tungsten molybdenum compound, an aluminum molybdenum compound and a titanium molybdenum compound.

In the array substrate of the present application, a grain distribution density in the seed layer is greater than a grain distribution density in the first metal layer.

In the array substrate of the present application, a grain size of the first metal layer close to the seed layer is greater than a grain size of the first metal layer away from the seed layer.

In the array substrate of the present application, the array substrate further includes a second metal layer disposed on the first metal layer, wherein materials of forming the second metal layer and the first metal layer are the same, and a grain size of the second metal layer is smaller than a grain size of the first metal layer.

The embodiment of the present application further provides a display panel including an array substrate. The array substrate includes: an underlay, a seed layer disposed on one side of the underlay, and a first metal layer disposed on one side of the seed layer and away from the underlay, wherein the first metal layer directly contacts the seed layer.

In the array substrate of the present application, a lattice structure of the first metal layer is the same as a lattice structure of the seed layer.

In the array substrate of the present application, a ratio of a difference between a lattice constant of the first metal layer and a lattice constant of the seed layer to the lattice constant of the first metal layer is smaller than or equal to 20%.

In the array substrate of the present application, a lattice constant of the first metal layer is the same as a lattice constant of the seed layer.

In the array substrate of the present application, the lattice structures of the first metal layer and the seed layer are body-centered cubic lattices, and the lattice constant is 3.14 pm.

In the array substrate of the present application, the seed layer has a thickness ranging from 50 to 1000 angstroms.

In the array substrate of the present application, a grain distribution density in the seed layer is greater than a grain distribution density in the first metal layer.

In the array substrate of the present application, a grain size of the first metal layer close to the seed layer is greater than a grain size of the first metal layer away from the seed layer.

In the array substrate of the present application, the array substrate further includes a second metal layer disposed on the first metal layer, materials of forming the second metal layer and the first metal layer are the same, and a grain size of the second metal layer is smaller than a grain size of the first metal layer.

In the array substrate of the present application, a material of the seed layer is at least one of tungsten, niobium, tantalum, a tungsten molybdenum compound, an aluminum molybdenum compound and a titanium molybdenum compound.

### Useful Effect

The present application discloses an array substrate and a display panel, wherein the array substrate includes an underlay, a seed layer disposed on one side of the underlay, and a first metal layer disposed on one side of the seed layer and away from the underlay. The first metal layer directly contacts the seed layer. The present application utilizes the seed layer directly contacting the first metal layer to induce the metal crystallization of the first metal layer, so that the first metal layer is formed with larger grains, fewer grain boundaries and less charge carrier scattering, and a resistivity of the first metal layer is decreased. The embodiment of the present application decreases the resistivity of the first metal layer without the precondition of increasing the masks.

### DESCRIPTION OF DRAWINGS

In order to explain the technical solution in the present application more clearly, the drawings required for the description of the embodiments will be briefly introduced. Obviously, the drawings in the following description only relate to some embodiments of the present application. Other drawings can be obtained from these drawings without creative works for those skilled in the art.

FIG. 1 is a schematic structure view showing a conventional array substrate.

FIG. 2 is a schematic structure view showing an array substrate provided by an embodiment of the present application.

FIG. 3 is another schematic structure view showing the array substrate provided by the embodiment of the present application.

FIG. 4 is a schematic comparison diagram showing grain sizes of first metal layers provided by the embodiment of the present application.

FIG. 5 is a schematic flow chart showing a method of manufacturing the array substrate provided by the embodiment of the present application.

FIG. 6 is a schematic structure view showing a display panel provided by the embodiment of the present application.

### DETAILED DESCRIPTION OF EMBODIMENTS

The technical solutions in the embodiments of the present application will be clearly and completely described below in conjunction with the drawings in the embodiments of the present application. Obviously, the embodiments described are only a part of the embodiments of the present application, rather than all the embodiments. Based on the embodiments in the present application, all other embodiments obtained by those skilled in the art without creative works should be deemed as falling within the claims of the present application.

In the description of this disclosure, it is to be understood that the terms “center,” “vertical,” “horizontal,” “length,” “width,” “thickness,” “upper,” “lower,” “front,” “rear,” “left,” “right,” “vertical,” “horizontal,” “top,” “bottom,” “inner,” “outer,” “clockwise,” “counterclockwise” and the like indicating the orientations or positional relationships are based on the orientations or positions shown in the drawings, and are only provided for the purposes of describing this disclosure and simplifying the description, but do not indicate or imply that the directed devices or elements must have the specific orientations, constructed and operated in the specific orientations, and thus cannot be understood as the restriction to this disclosure. In addition, the terms “first” and “second” are only used for descriptive purposes, and cannot be understood as indicating or implying relative importance or implicitly indicating the number of technical features as indicated. Thus, the feature defined with “first” and “second” may explicitly or implicitly include one or multiple features. In the description of this disclosure, the meaning of “multiple” includes two or more than two unless otherwise specified.

In the description of this disclosure, it is to be described that, unless otherwise expressly stated and limited, the terms “mount,” “link,” and “connect” should be broadly understood, may be, for example: the fixed connection, the detachable connection or the integral connection; the mechanical connection, electrical connection or mutual communication; the direct connection, the indirect connection through a middle medium, or the internal communication or interaction between two elements. It will be apparent to those skilled in the art that the specific meaning of the above-mentioned terms in the present application can be understood according to the specific condition.

In the present application, unless otherwise expressly stated and limited, the first feature being disposed “on” or “under” the second feature may include the condition that the first feature directly contacts the second feature, and may also include the condition that the first feature indirectly contacts the second feature through another feature disposed therebetween. In addition, the first feature being disposed above, over or on the second feature includes the condition that the first feature is disposed directly and obliquely above the second feature, or only the condition that the level of the first feature is higher than that of the second feature. The first feature being disposed under, below or beneath the second feature includes the condition that the first feature is disposed directly and obliquely below the second feature, or only the condition that the level of the first feature is lower than that of the second feature.

The following disclosure provides many different implementations or examples for realizing different structures of the present application. In order to simplify the disclosure of the present application, the components and configurations of specific examples are described hereinbelow. Of course, they are only examples, and are not intended to limit the present application. In addition, reference digits and/or reference characters may be repeated in different examples of the present application, such the repetition is for the purpose of simplification and clarity, and does not in itself indicate the relationship between the various embodiments and/or configurations discussed. In addition, the present application provides examples of various specific processes and materials, but those of ordinary skill in the art may be aware of the application of other processes and/or the use of other materials.

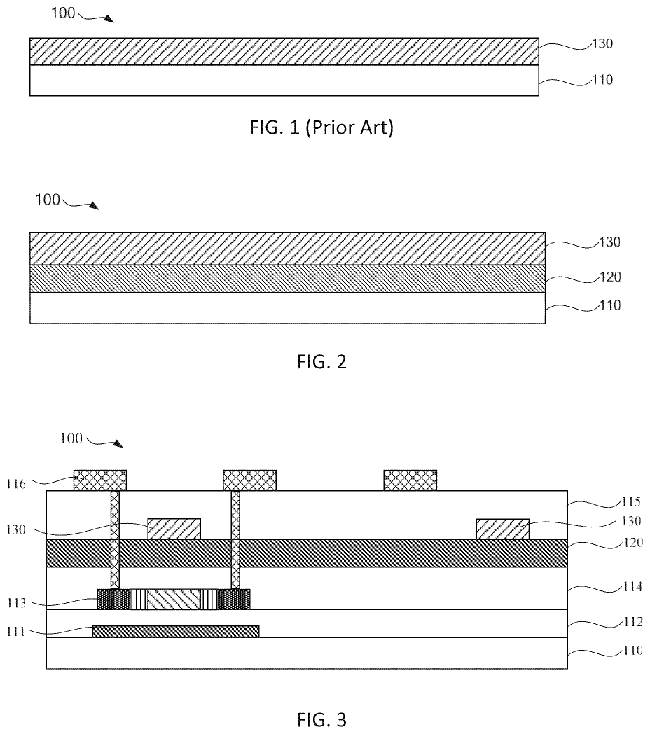

In the prior art, the first metal layer wire in the display panel is restricted by the high-temperature process, and the molybdenum (Mo) metal is mostly used at present. Referring to FIG. 1, an array substrate 100 includes an underlay 110, and a first metal layer 130 disposed on the underlay 110. The material forming the first metal layer 130 is the Mo metal. However, the Mo metal has the higher impedance, which is disadvantageous to the product requirement of the high charging rate of the high resolution, high frequency and middle-size product. The present application proposes the following technical solutions to solve the above-mentioned technical problems.

FIG. 2 is a schematic structure view showing the array substrate provided by the embodiment of the present application. The array substrate 100 includes an underlay 110, a seed layer 120 disposed on one side of the underlay 110, and a first metal layer 130, which is disposed on one side of the seed layer 120 and away from the underlay 110, and directly contacts the seed layer 120. The underlay 110 may be a rigid underlay substrate, and may also be a flexible underlay substrate. A material forming the underlay 110 includes one of glass, quartz, polyimide and the like.

The grain size of the first metal layer 130 is greater than a first threshold value, which is the grain size of the first metal layer 130 when no seed layer 120 is provided. If the grain size of the first metal layer 130 formed when no seed layer 120 is provided is 27.5 nm, then the first threshold value is 27.5 nm.

In this embodiment, providing the seed layer 120 directly contacting the first metal layer 130 makes the Mo metal grow on the seed layer 120. That is, the seed layer 120 is utilized to induce the crystallization of the first metal layer 130, so that the first metal layer 130 is formed with the larger grain, fewer grain boundaries and less charge carrier scattering, thereby decreasing the resistivity of the first metal layer 130.

In the present application, the resistivity of the first metal layer 130 is decreased without the preconditions of modifying the machine and increasing the masks, thereby providing a solution for high-temperature withstanding first metal layer having the low resistance for the medium and large-size display products, and enhancing the competitiveness of the display panel.

An arbitrary one of the thin film transistors will function as an example for the explanation of the structure of the array substrate in the present application. Referring to FIG. 3, the array substrate 100 includes an underlay 110, a light-obstructing layer 111, a buffer layer 112, a semiconductor layer 113, a gate insulating layer 114, a seed layer 120, a first metal layer 130, an interlayer insulating layer 115 and a second metal layer 116 sequentially stacked and arranged. In other embodiments, the array substrate 100 may further include more other film layers.

The light-obstructing layer 111 is disposed on the underlay 110 and is patterned. The patterning represents performing processes, such as exposure, etching and the like, on a material of the light-obstructing layer coated on the entire underlay 110 to finally form the patterned light-obstructing layer 111. The material of the light-obstructing layer 111 may be, for example, a molybdenum aluminum alloy, a chromium metal, a molybdenum metal or any other material having both the light-obstructing function and electroconductivity. The buffer layer 112 is disposed on the light-obstructing layer 111 and the underlay 110. The semiconductor layer 113 is disposed on the buffer layer 112, and is an active layer formed by patterning. The gate insulating layer 114 is disposed on the semiconductor layer 113 and the buffer layer 112. The gate insulating layer 114 may be formed by one of materials including silicon oxide (SiOx), silicon nitride (SiNx), silicon oxy-nitride (SiNxOy) and the like.

The seed layer 120 is disposed on the gate insulating layer 114. The first metal layer 130 is formed on the seed layer 120, and then exposure and etching are performed on the first metal layer 130 to form the patterned first metal layer 130. The patterned first metal layer 130 includes a gate layer. The material forming the first metal layer is a high-temperature withstanding electroconductive material, such as the metal Mo.

The interlayer insulating layer 115 is disposed on the first metal layer 130 and the gate insulating layer 114. The second metal layer 116 is formed on the interlayer insulating layer, and then exposure and etching are performed on the second metal layer 116 to form the patterned second metal layer 116 including a source-drain layer.

In one embodiment, a lattice structure of the seed layer 120 is the same as a lattice structure of the first metal layer 130. For example, the lattice structure is a body-centered cubic lattice or a face-centered cubic lattice or a hexagonal close-packed lattice. The seed layer 120 and the first metal layer 130 have the same lattice structure to enhance the property that the seed layer 120 induces the metal crystallization effect in the first metal layer 130.

In one embodiment, a lattice constant of the seed layer 120 approaches a lattice constant of the first metal layer 130. The lattice constant refers to a side length of a crystal cell (i.e., a side length of each parallelepiped cell). For example, a ratio of a difference between the lattice constant of the first metal layer 130 and the lattice constant of the seed layer 120 to the lattice constant of the first metal layer 130 is smaller than or equal to 20%. In some cases, the lattice constant of the seed layer 120 is the same as the lattice constant of the first metal layer 130.

Using the seed layer 120 having the lattice constant, which is the same as or approaches the lattice constant of the first metal layer 130 can enhance the lattice constant of the seed layer and the metal crystallization effect in the first metal layer 130.

In one embodiment, the lattice structure of the seed layer 120 is the same as the lattice structure of the first metal layer 130, and the lattice constant of the seed layer 120 is the same as or approaches the lattice constant of the first metal layer 130. More particularly, in the condition that the lattice structure of the seed layer 120 is the same as the lattice structure of the first metal layer 130, and the lattice constant of the seed layer 120 is the same as the lattice constant of the first metal layer 130, the metal crystallization effect in the first metal layer 130 becomes the best. For example, the induced crystallization has the best orderliness, the formed grain size becomes the maximum, the grain becomes the most uniform, the crystallization boundary becomes the minimum, and the charge carrier scattering becomes the least, thereby minimizing the resistivity of the first metal layer 130.

For example, the lattice structure of each of the first metal layer 130 and the seed layer 120 is the body-centered cubic lattice, and the lattice constant of each of the first metal layer 130 and the seed layer 120 is equal to 3.14 picometers (pm).

The thickness of the seed layer 120 ranges from 50 to 1000 angstroms. The thickness of the first metal layer 130 can be determined according to the requirement of the actually required array substrate, and the thickness of the first metal layer 130 is inversely proportional to the resistance of the first metal layer 130. After the seed layer 120 has reached a predetermined thickness, such as the thickness corresponding to the above-mentioned thickness range, there is no much change in the resistivity caused by the increase of the thickness, and the thickness of the array substrate 100 and the cost are increased.

The material of the seed layer 120 may be at least one of tungsten, niobium, tantalum, a tungsten molybdenum compound, an aluminum molybdenum compound and a titanium molybdenum compound, wherein the tungsten molybdenum compound includes MoW₅₀, the aluminum molybdenum compound includes MoAl₂₀ and MoAl₂₀Ti₁₀, and the titanium molybdenum compound includes MoTi₅₀ and the like.

In the above-mentioned embodiment, because the seed layer 120 induces the metal crystallization in the first metal layer 130, the grain size in the seed layer 120 is smaller than the grain size in the first metal layer 130. Correspondingly, the grain distribution density in the seed layer 120 is greater than the grain distribution density in the first metal layer 130.

In the above-mentioned embodiment, a grain size of the first metal layer 130 close to the seed layer 120 is greater than a grain size of the first metal layer 130 away from the seed layer 120. This is because the grain crystallization in the first metal layer close to the seed layer 120 firstly occurs, and the grain having the larger size falls down owing to the gravity reason.

In the above-mentioned embodiment, the array substrate further includes the second metal layer 116 disposed on the first metal layer 130. When the materials of forming the first metal layer 130 and the second metal layer 116 are the same, such as Mo, the grain size of the second metal layer 116 is smaller than the grain size of the first metal layer 130 because the seed layer 120 is used to induce the metal crystallization in the first metal layer 130.

In one embodiment, when the materials of the first metal layer 130 and the second metal layer 116 are the same and the grain size of the second metal layer 116 is smaller than the grain size of the first metal layer 130, the second metal layer 116 may overlap with the first metal layer 130 to form a capacitor. In the embodiment, the first metal layer 130 may be the gate layer, the second metal layer 116 may also be the metal layer but is not the source-drain layer.

In one embodiment, the grains in the first metal layer 130 close to the seed layer 120 are larger and are more uniformly distributed, while the grains in the first metal layer 130 away from the seed layer 120 are smaller and have the lower uniformity.

In one embodiment, the grain sizes in the middle region are greater than the grain sizes on two sides in the first metal layer 130. Thus, the property that the impedance of the marginal region is greater than the impedance of the middle region can be implemented to avoid overload, and this is equivalent to provide the marginal region of the first metal layer functioning as a protection layer.

In the above-mentioned array substrate 100, compared with the condition of not adopting the seed layer 120, adopting the seed layer 120 to induce the crystallization of the first metal layer 130 can form the larger grains in the first metal layer 130, obtain the less charge carrier scattering at the grain boundaries, and decrease the impedance of the first metal layer 130. Compared with the condition of not adopting the seed layer 120, adopting the seed layer 120 to induce the crystallization of the first metal layer 130 can decrease the impedance in the first metal layer 130 by 30%, thereby obtaining the high-temperature withstanding and low impedance array substrate.

The correspondingly measured coherent diffraction domain size of the grain size in the first metal layer 130 obtained by adopting the seed layer 120 to induce the crystallization of the first metal layer 130 is greater than the corresponding coherent diffraction domain size obtained when no seed layer 120 is adopted. The greater coherent diffraction domain size represents the larger grain and corresponds to the smaller resistivity. In addition, the grain size of the first metal layer 130 obtained by adopting the seed layer 120 to induce the crystallization of the first metal layer 130 is greater than the grain size correspondingly obtained when no seed layer 120 is adopted. The specific details are listed in Table 1.

Table 1 lists the comparison between the corresponding diffraction domain sizes and the grain sizes when the seed layer is adopted and no seed layer is adopted.

| | Coherent diffraction | Grain |
|---|---|---|
| Thin film layer | domain size (nm) | size (nm) |
| First metal layer (Mo) | 48.7 | 27.5 |
| Seed layer + first | 62.7 | 38.7 |
| metal layer (Mo) | | |

It is obtained, from Table 1, that: when the seed layer 120 is adopted, the corresponding coherent diffraction domain size is equal to 62.7 nm, and the grain size is equal to 38.7 nm; and when no seed layer 120 is adopted, the corresponding coherent diffraction domain size is equal to 48.7 nm, and the grain size is equal to 27.5 nm. It is to be noted that the size in Table 1 and the embodiment of the present application is the average size.

The corresponding size of either the coherent diffraction domain size or the grain size obtained when the seed layer 120 is adopted is greater than the corresponding size obtained when no seed layer 120 is adopted. The seed layer 120 is adopted to induce the crystallization of the first metal layer 130, so that the first metal layer is formed with larger grains, fewer grain boundaries and less charge carrier scattering, and a resistivity of the first metal layer is decreased.

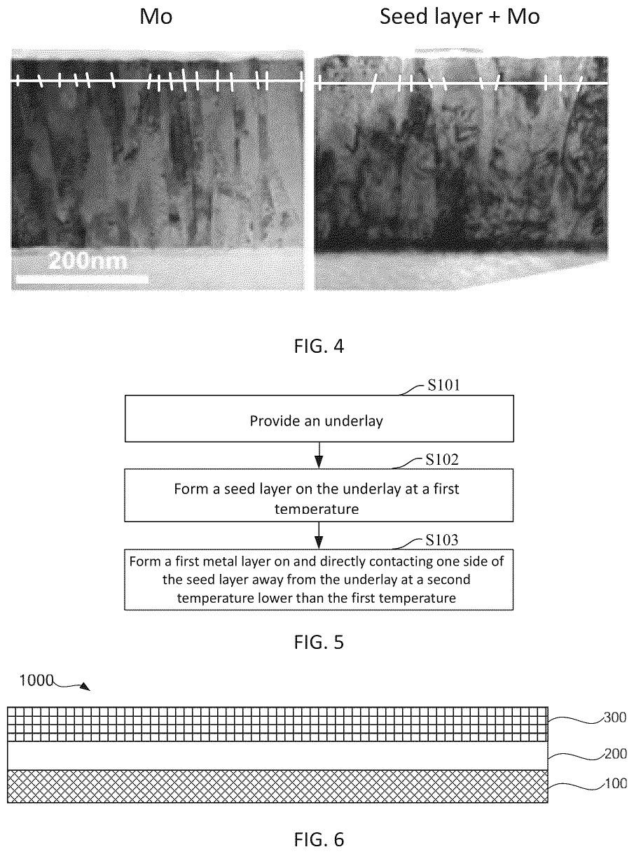

FIG. 4 is a schematic comparison diagram showing grain sizes of first metal layers provided by the embodiment of the present application. Referring to FIG. 4, the longer horizontal lines are reference lines, a distance between two irregular separators indicates a distance between the grain boundaries, and corresponds to the grain size. The left part of the figure corresponds to the grain size of the first metal layer correspondingly obtained when no seed layer 120 is used, and the right part of the figure corresponds to the grain size of the first metal layer correspondingly obtained when the seed layer 120 is used. It is obtained that the (average) grain size in the right part of the figure is greater than the (average) grain size in the left part of the figure.

In the above-mentioned embodiment, providing the seed layer 120 to implement the growth of the Mo metal of the first metal layer 130 on the seed of the seed layer 120, and utilizing the seed layer 120 to induce the Mo metal crystallization can enlarge the grain in the first metal layer 130, decrease the grain boundaries, decrease the charge carrier scattering at the grain boundaries, decrease the charge carrier scattering, and decrease the resistivity of the first metal layer 130. The embodiment of the present application can decrease the resistivity of the first metal layer 130 without the preconditions of modifying the machine and increasing the masks.

FIG. 5 is a schematic flow chart showing a method of manufacturing the array substrate provided by the embodiment of the present application. The method of manufacturing the array substrate includes the following steps S101 to S103.

In S101, an underlay is provided.

In S102, a seed layer is formed on the underlay at a first temperature.

The seed layer 120 is deposited on the underlay 110 at the first temperature. When the seed layer 120 is deposited, the corresponding power of constructing the apparatus needs to be higher than or equal to 40 KW, and the pressure of depositing the seed layer 120 needs to be lower than or equal to 0.4 Pa.

The first temperature may be any temperature ranging from 150 to 300 degrees, such as 200 degrees and the like.

Specifically, the seed layer 120 may be formed by one of a physical vapor deposition process, a magnetron sputtering process and the like.

In S103, a first metal layer is formed on one side of the seed layer away from the underlay at a second temperature, wherein the first temperature is higher than the second temperature, and the first metal layer directly contacts the seed layer.

Because the first temperature of forming the seed layer is higher than the second temperature of forming the first metal layer, the seed layer 120 and the first metal layer 130 can be formed in different chambers at different temperatures.

The first temperature is higher than the second temperature, so that the formed seed layer 120 has the better compactness, fewer defects and better crystal forms, and this is beneficial to the Mo grain growth of the first metal layer 130. Using the first metal layer 130 directly contacting the seed layer 120 and the seed layer 120 to induce the metal crystallization in the first metal layer 130 is beneficial to the Mo grain growth of the first metal layer 130.

In the array substrate 100 formed in the embodiment, the seed layer is formed, and the first metal layer 130 is formed on the seed layer utilized to induce the metal crystallization of the first metal layer, so that the first metal layer is formed with larger grains, fewer grain boundaries and less charge carrier scattering, and the resistivity of the first metal layer is decreased. The embodiment decreases the resistivity of the first metal layer 130 without the preconditions of modifying the machine and increasing the masks.

In other embodiments, the light-obstructing layer 111, the buffer layer 112, the semiconductor layer 113 and the gate insulating layer 114 are formed on the underlay 110 in order, the seed layer 120 is formed on the gate insulating layer 114, the first metal layer 130 is formed on the seed layer 120, and the first metal layer 130 is patterned to obtain the patterned first metal layer 130. The interlayer insulating layer 115 and the second metal layer 116 are formed on the patterned first metal layer 130 and the gate insulating layer 114 in order.

The embodiment of the present application further provides a display panel including the array substrate corresponding to any one of the above-mentioned embodiments, wherein the contents and corresponding useful effects of the array substrate have been described in the above-mentioned.

In one embodiment, the display panel further includes a color filter substrate disposed opposite the array substrate, and a liquid crystal layer disposed between the array substrate and the color filter substrate.

In one embodiment, the display panel further includes a light-emitting layer, which is disposed on the array substrate and may include a light-emitting device, such as any one of an organic light-emitting diode (OLED), a mini-LED, a micro-LED and the like.

FIG. 6 is a schematic structure view showing a display panel 1000 provided by the embodiment of the present application. The display panel 1000 includes the array substrate 100, a color filter substrate 300 disposed opposite the array substrate, and a liquid crystal layer 200 disposed between the array substrate 100 and the color filter substrate 300.

The present application discloses an array substrate, a method of manufacturing the array substrate, and a display panel. The array substrate includes an underlay, a seed layer disposed on one side of the underlay, and a first metal layer disposed on one side of the seed layer and away from the underlay, wherein a grain size of the first metal layer is greater than a first threshold value. The present application only utilizes the seed layer to induce the metal crystallization of the first metal layer without the preconditions of modifying the machine and increasing the masks, so that the first metal layer is formed with larger grains, fewer grain boundaries and less charge carrier scattering, and a resistivity of the first metal layer is decreased. Thus, a solution for high-temperature withstanding first metal layer having the low resistance is provided to the medium and large-size display products, and the competitiveness of the display panel is enhanced.

In the above-mentioned embodiments, the description of each embodiment has its own focus. For parts that are not described in detail in one embodiment, reference can be made to the relevant description of other embodiments.

An electric device provided by the embodiments of the present application has been described in detail hereinabove. In this disclosure, the description of the above-mentioned embodiments is only used to help readers understand the technical solutions and core ideas of the present application. Those of ordinary skill in the art should understand that: they can still modify the technical solutions described in the foregoing embodiments, or equivalently replace some of the technical features; and these modifications or replacements do not cause the essence of the corresponding technical solutions to deviate from the scope of the technical solutions of the embodiments of the present application.

What is claimed is:

1. An array substrate, comprising: an underlay, a seed layer disposed on one side of the underlay, and a first metal layer disposed on one side of the seed layer and away from the underlay,
wherein the first metal layer directly contacts the seed layer.

2. The array substrate according to claim 1, wherein a lattice structure of the first metal layer is the same as a lattice structure of the seed layer.

3. The array substrate according to claim 2, wherein a ratio of a difference between a lattice constant of the first metal layer and a lattice constant of the seed layer to the lattice constant of the first metal layer is smaller than or equal to 20%.

4. The array substrate according to claim 3, wherein the lattice constant of the first metal layer is the same as the lattice constant of the seed layer.

5. The array substrate according to claim 4, wherein the lattice structures of the first metal layer and the seed layer are body-centered cubic lattices, and the lattice constant is 3.14 pm.

6. The array substrate according to claim 1, wherein the seed layer has a thickness ranging from 50 to 1000 angstroms.

7. The array substrate according to claim 1, wherein a grain distribution density in the seed layer is greater than a grain distribution density in the first metal layer.

8. The array substrate according to claim 1, wherein a grain size of the first metal layer close to the seed layer is greater than a grain size of the first metal layer away from the seed layer.

9. The array substrate according to claim 1, further comprising a second metal layer disposed on the first metal layer, wherein materials of forming the second metal layer and the first metal layer are the same, and a grain size of the second metal layer is smaller than a grain size of the first metal layer.

10. The array substrate according to claim 1, wherein a material of the seed layer is at least one of tungsten, niobium, tantalum, a tungsten molybdenum compound, an aluminum molybdenum compound and a titanium molybdenum compound.

11. A display panel, comprising an array substrate, the array substrate comprising: an underlay, a seed layer disposed on one side of the underlay, and a first metal layer disposed on one side of the seed layer and away from the underlay,
wherein the first metal layer directly contacts the seed layer.

12. The display panel according to claim 11, wherein a lattice structure of the first metal layer is the same as a lattice structure of the seed layer.

13. The display panel according to claim 12, wherein a ratio of a difference between a lattice constant of the first metal layer and a lattice constant of the seed layer to the lattice constant of the first metal layer is smaller than or equal to 20%.

14. The display panel according to claim 13, wherein the lattice constant of the first metal layer is the same as the lattice constant of the seed layer.

15. The display panel according to claim 14, wherein the lattice structures of the first metal layer and the seed layer are body-centered cubic lattices, and the lattice constant is 3.14 pm.

16. The display panel according to claim 11, wherein the seed layer has a thickness ranging from 50 to 1000 angstroms.

17. The display panel according to claim 11, wherein a grain distribution density in the seed layer is greater than a grain distribution density in the first metal layer.

18. The display panel according to claim 11, wherein a grain size of the first metal layer close to the seed layer is greater than a grain size of the first metal layer away from the seed layer.

19. The display panel according to claim 11, wherein the array substrate further comprises a second metal layer disposed on the first metal layer, materials of forming the second metal layer and the first metal layer are the same, and a grain size of the second metal layer is smaller than a grain size of the first metal layer.

20. The display panel according to claim 11, wherein a material of the seed layer is at least one of tungsten, niobium, tantalum, a tungsten molybdenum compound, an aluminum molybdenum compound and a titanium molybdenum compound.
